(19) United States
(12) Patent Application Publication
(10) Pub. No.: US 2014/0374855 A1
(43) Pub. Date: Dec. 25, 2014

(54) PRESSURE SENSOR AND METHOD OF PACKAGING SAME

(71) Applicant: Wai Yew Lo, Petaling Jaya (MY)

(72) Inventor: Wai Yew Lo, Petaling Jaya (MY)

(21) Appl. No.: 13/924,633

(22) Filed: Jun. 24, 2013

(51) Int. Cl. B81B 7/00; B81B 3/00; B81C 1/00

(52) U.S. Cl. CPC B81B 7/0058; B81C 1/00301; B81B 3/0021; B81C 1/00269; B81C 1/00333; B81B 2201/0235; B81B 2201/0242; B81B 2201/0264
USPC 257/417; 438/51

(57) ABSTRACT

A method of packaging a pressure sensor die begins with patterning and etching a metal strip and forming metal traces on the strip. Further build-up is performed to transform the metal strip into a layered substrate. Cavity walls are formed on one side of the strip with a molding process and then the metal on the back side of the strip is removed. Next semiconductor dies are attached to the strip within the cavities and electrically connected to pads formed on the surface of the strip and/or to pads on other ones of the dies. A gel coating is deposited over the dies and then a metal lid is secured over the cavity. The strip is then singulated along ones of the cavity walls to form multiple sensor devices.

### BACKGROUND OF THE INVENTION

The present invention relates generally to pressure sensor devices, and more particularly to a method of assembling pressure sensor devices.

Various types of sensors now are widely used in electronic devices such as mobile phones, mobile computing devices, and automotive electronics. For example, pressure sensors and accelerometers may be packaged together with a microcontroller that processes the sensor data to provide useful output data. Such sensor packages require a small form factor, low power, and competitive pricing. Thus, it is important to be able to assemble such devices using a process that is cost efficient and reliable.

The pressure sensor die typically has a thin differential pressure-sensing membrane that is susceptible to mechanical damage during handling and packaging. One way of packaging the pressure sensor die is mounting the die to a premolded lead frame and encapsulating the package with a mold compound. However, such pre-molded lead frames are expensive. Further, dies such as piezo resistive transducer (PRT) dies do not allow full encapsulation because that would impede their functionality. As a result, the premolded lead frame requires a metal lid or cap be placed over the die to protect it from the outside environment.

It would be advantageous to be able to efficiently package pressure sensor dies in which the risk of environmental damage to the pressure sensor die is substantially reduced or eliminated while reducing the overall packaging costs.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 is a top, cross-sectional view of a pressure sensor package in accordance with one embodiment of the present invention;

FIG. 2 is a side, cross-sectional view of the pressure sensor package of FIG. 1; and

FIGS. 3A-3V are side cross-sectional views illustrating a various steps of a method for assembling the pressure sensor package shown in FIGS. 1 and 2.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved. Unless stated otherwise, terms such as “first” and “second” are used to arbitrarily distinguish between the elements such terms describe. Thus, these terms are not necessarily intended to indicate temporal or other prioritization of such elements.

This present invention provides a pre-molded, coreless package for a pressure sensor die and other dies such as a microcontroller (MCU) and other sensor dies like a G-cell or gyro. Some of the main features of the package include a coreless carrier, pre-molded side walls, and a metal lid. Wires for interconnection for the pressure sensor die and/or combination of other dies such as MCU, G-cell, and Gyro, and silicone gel are some of the main internal features of the package.

In one embodiment, the present invention provides a method of packaging a pressure sensor die. The method includes forming a coreless substrate on a sheet of metal foil. The forming includes forming one or more die attach areas and a plurality of electrical contacts on an upper surface of the substrate. The method also includes forming side walls at predetermined locations on the upper substrate upper surface. A first die such as a micro-control unit or control die is attached to a first one of the die attach areas with a die attach adhesive and a pressure sensor die is attached to a second one of the die attach areas, also with a die attach adhesive. The die attach adhesive is then cured and bond pads of first die are electrically connected to the plurality of electrical contacts on the substrate upper surface, and bond pads of the pressure sensor die are electrically connected to the first die. A gel is dispensed onto a top surface of at least the pressure sensor die. The gel is cured and a lid is attached to the side walls such that the lid covers the first die and the pressure sensor die. The lid attach adhesive then is cured. In an alternative embodiment, an accelerometer also is packaged within the side walls and covered with the lid.

In another embodiment, the present invention is a packaged pressure sensor die formed in accordance with the above-described method.

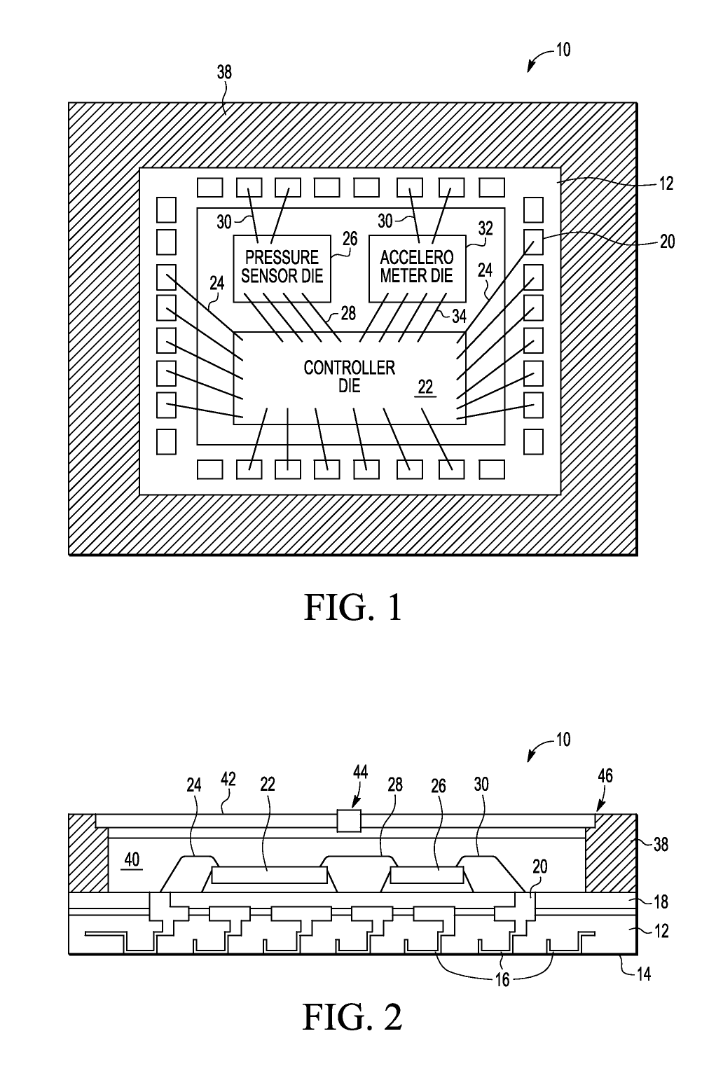

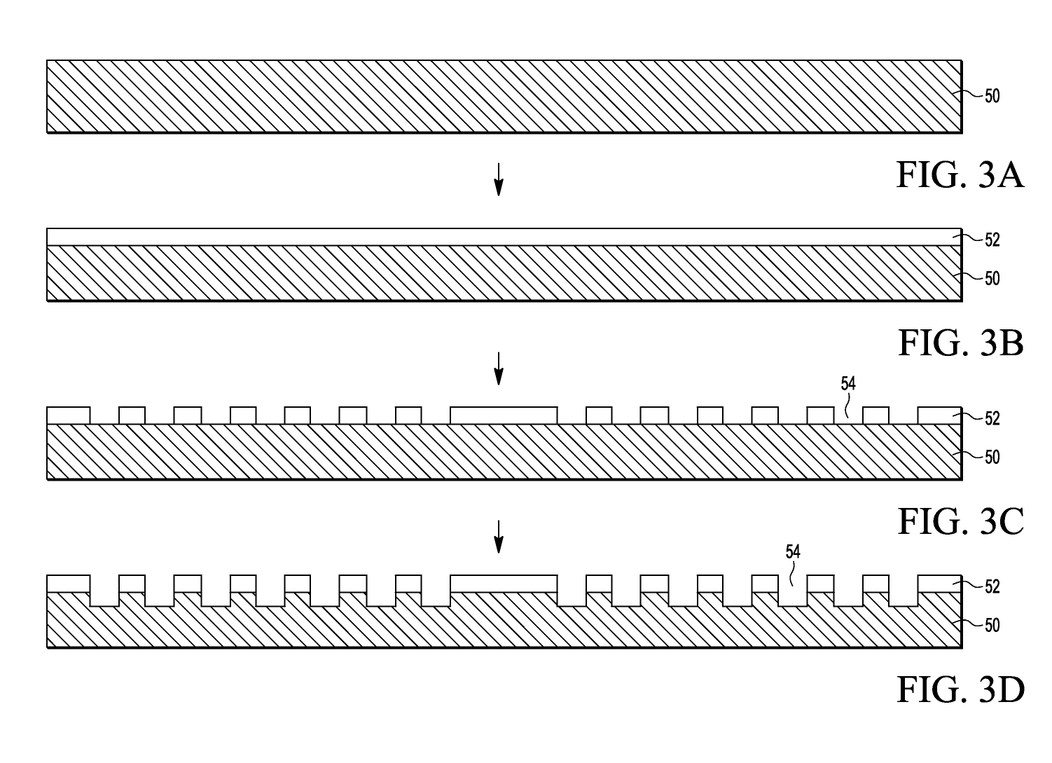

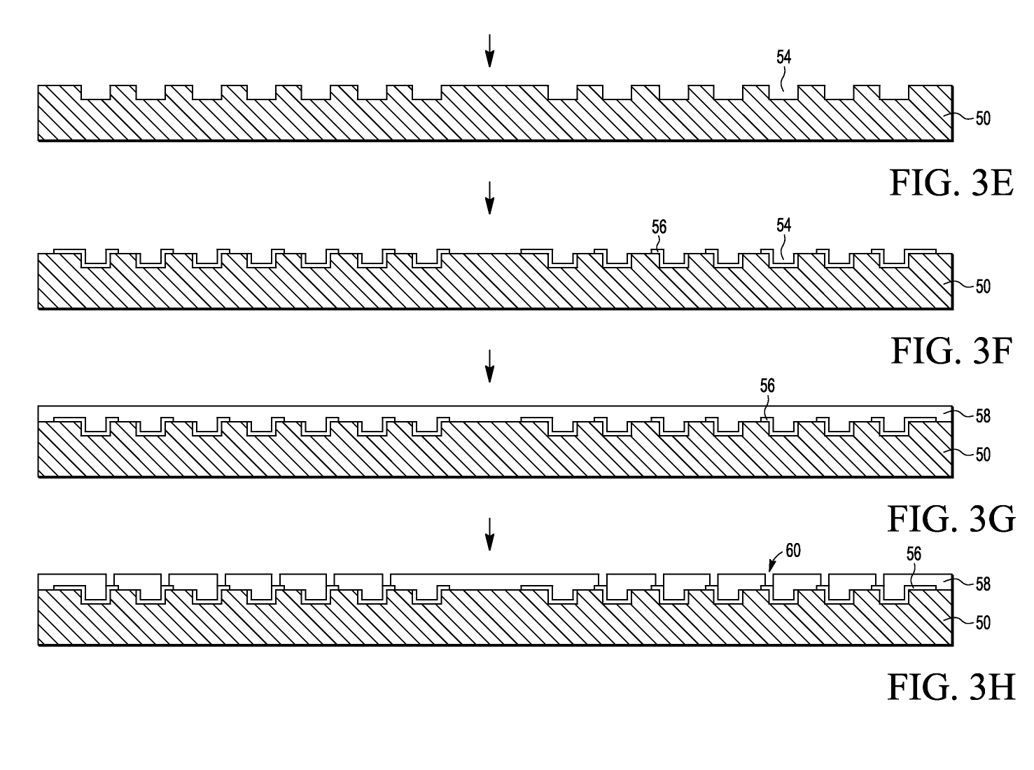

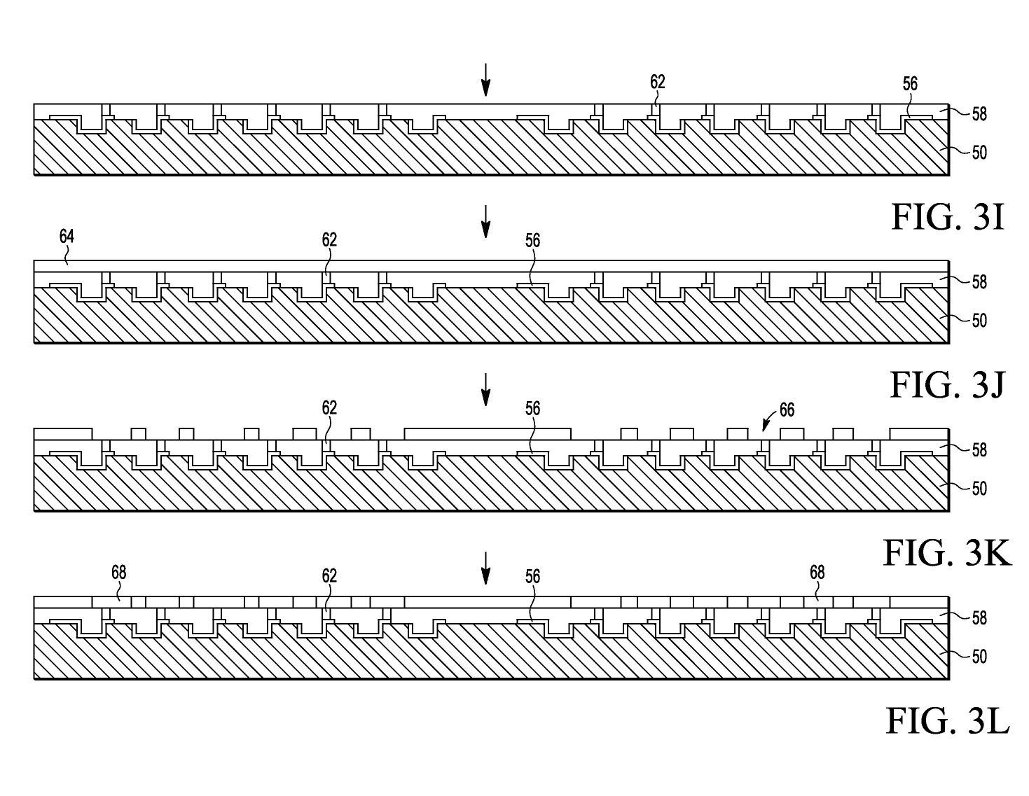

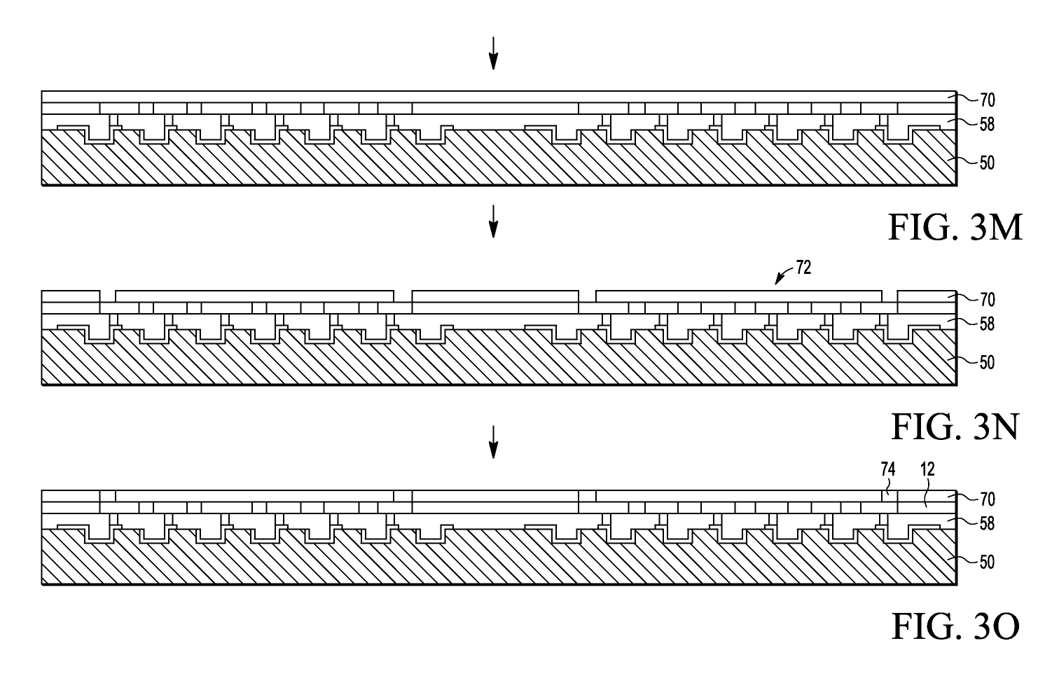

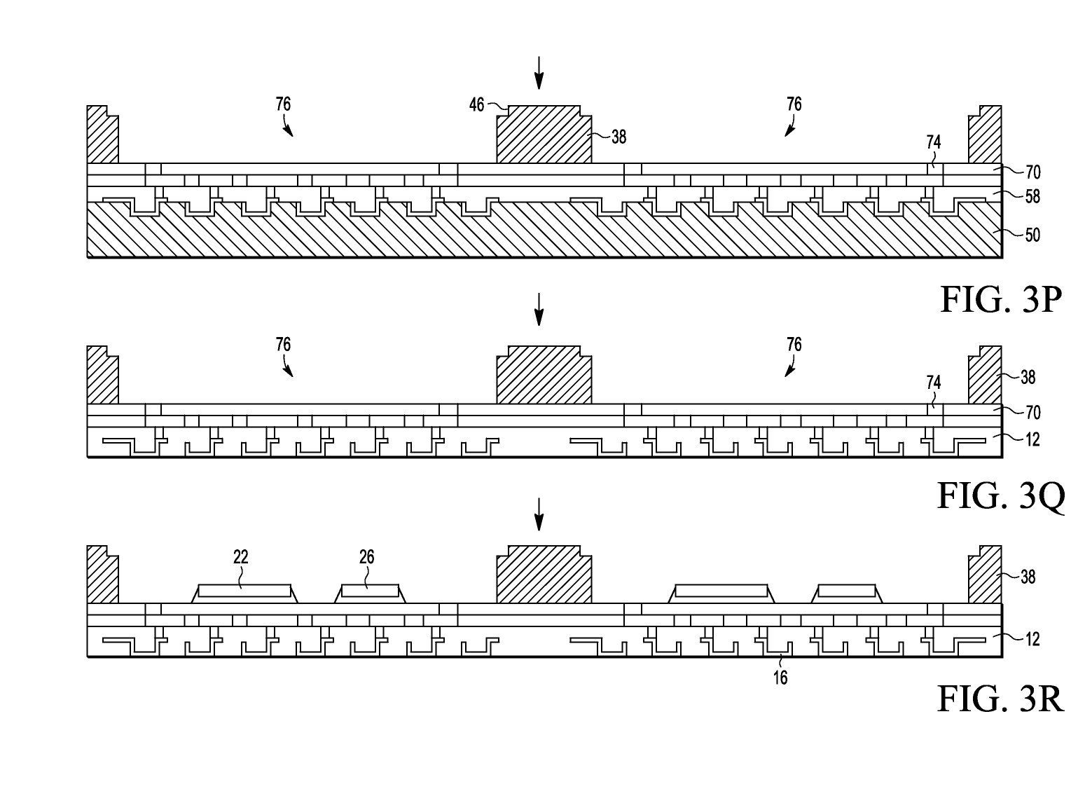

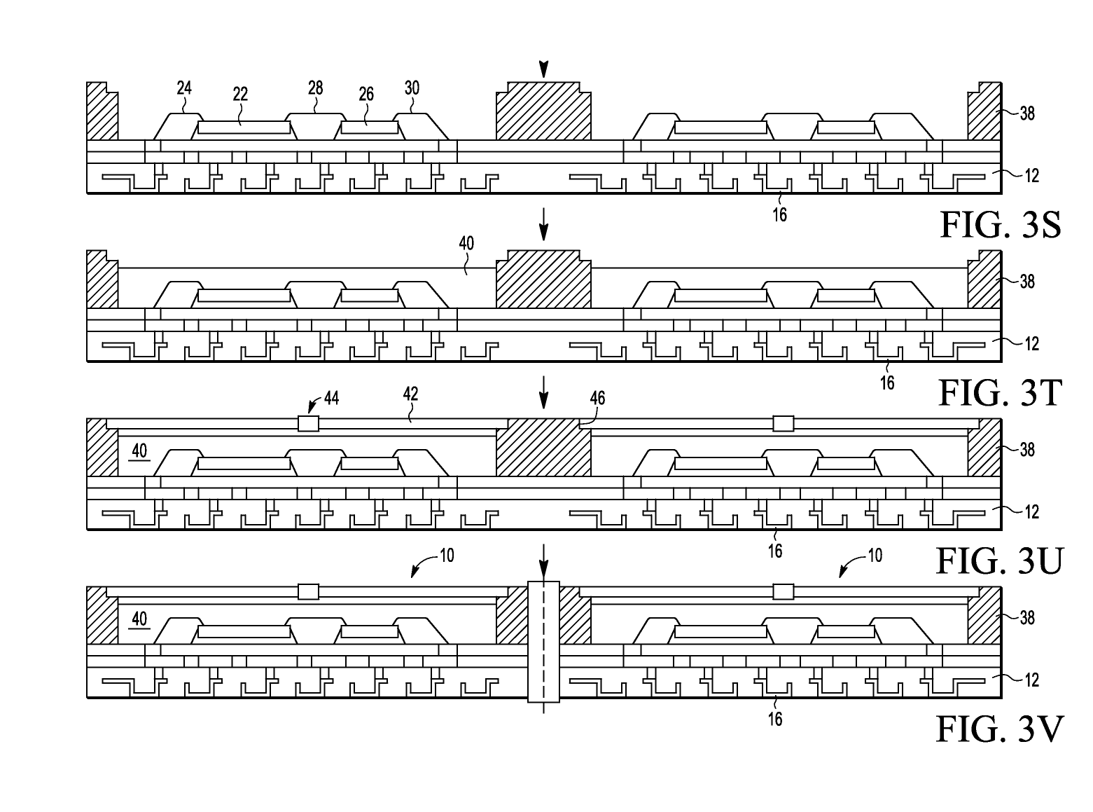

Referring now to FIGS. 1 and 2, a top, cross-sectional view and a side cross-sectional view of a packaged pressure sensor die 10 according to an embodiment of the present invention is shown. The packaged die 10 includes a coreless substrate 12 having a lower surface 14 with exposed electrical contacts 16 and an upper surface 18 with exposed substrate contact pads 20 and one or more die attach areas. The substrate 12 will be described in more detail with reference to FIG. 3.

A first die 22 is attached to a first die attach area and electrically connected to the substrate contact pads 20. In one embodiment, the first die is a microcontroller or MCU die. However, the first die 22 also could be an Application Specific Integrated Circuit (ASIC). The first die 22 is in electrical communication with the substrate 12. More specifically, bonding pads on an active surface of the first die 22 are electrically connected to the contact pads 20 on the upper surface 18 of the substrate 12 with first bond wires 24. A pressure sensor die 26 is attached to a second die attach area on the upper surface 18 of the substrate 12 and electrically connected to the first die 22 with second bond wires 28. The pressure sensor die 26 also may be electrically connected to the exposed contact pads 20 on the upper surface 18 of the substrate 12 with third bond wires 30. As can be seen in FIG. 1, a second sensor die 32 is attached to a third die attach area on the upper surface 18 of the substrate 12 and electrically connected to the first die 22 with fourth bond wires 34. The second sensor die 32 also may be electrically connected to the exposed contact pads 20 on the upper surface 18 of the substrate 12 with fourth bond wires 36. The first through fifth bond wires 24, 28, 30, 34, 36 may be formed of gold, aluminium, silver or copper and are well known and commercially available, and may be attached using conventional wire bonding equipment. The first die 22, pressure sensor die 26, and second sensor die 32 may be attached to the substrate 12 using conventional die attach adhesive, die attach film or even a double sided tape, also as is known in the art.

The pressure sensor die 22 may take various forms, such as a piezo resistive transducer (PRT) or a pressure sensor cell (P-cell) and the second sensor die 32 may be an accelerometer.

A side wall 38 is formed on the upper surface 18 of the substrate 12. The side wall 38 surrounds the dies 22, 26 and 32. The side wall 28 may be formed of a molding compound, plastic material, epoxy, silica-filled resin, ceramic, halide-free material, and the like, or combinations thereof, as is known in the art, and may be formed with a conventional molding process.

A gel 40 is dispensed over at least the pressure sensor die 26 and in the embodiment shown, the gel 40 covers each of the dies 22, 26 and 32. The gel 40 comprises a pressure-sensitive gel material, such as a silicon-based gel. The pressure-sensitive gel 40 enables the pressure of the ambient atmosphere to reach the pressure-sensitive active region of pressure sensor die 26, while protecting the die 26 and the bond wires 24, 28, 30, 34 and 36 from mechanical damage during packaging and environmental damage (e.g., contamination and/or corrosion) when in use. Examples of a suitable pressure-sensitive gel 40 are available from Dow Corning Corporation of Midland, Michigan.

A lid 42 is supported by the side walls 38 and covers the gel covered control die 22, the pressure sensor die 26 and the accelerometer 32. The sidewalls 38 may include notches 46 that receive ends of the lid 42. The lid 42 may be secured within the notches 46 and to the side walls 38 with an adhesive. The lid 42 preferably is formed of metal and includes a through hole 44. The hole 44 allows the ambient atmospheric pressure immediately outside the sensor device 10 to reach the pressure-sensitive gel 40 and therethrough the active region of pressure sensor die 26. The hole 44 can be located anywhere within the area of the lid 42. The hole 44 may be (pre-)formed in the lid 42 by a known fabrication process such as drilling or punching.

Referring now to FIGS. 3A-3V, a process for assembling the pressure sensor die package 10 will be described. FIG. 3A is a side view showing a strip or sheet of copper foil 50 that is used as a starting point for forming the substrate 12 (FIG. 1). The copper foil 50 preferably comprises a bare copper foil sheet. The foil 50 is sized and shaped for the formation of the substrate 12 upon which a plurality of the packaged dies 10 may be simultaneously formed. For example, a 75 mm×240 mm sheet of bare copper may be used. Next, as shown in FIG. 3B, the foil 50 is coated with a resist coating or a dry film lamination 52. The coating is required for subsequent patterning processes to define metal traces to establish interconnection between the dies and the pads 16 on the bottom side of the substrate 12. The resist coating 52 is developed (FIG. 3C), which forms channels 54 in the coating 52. At FIG. 3D, the copper foil 50 is etched at the channels 54, which increases the depth of the channels 54. For example, the channels 54 may be etched to a depth of between 25 um to 100 um depending on the final thickness of the substrate 12. FIG. 3E shows the resist coating 52 being stripped off of the foil 50, such as by machine or manual process. At FIG. 3F, the top surface of the foil 50 is patterned and a trace metal 56 is deposited on the surface of the foil 50 such as by electroplating. The trace metal 56 comprises a conductive metal or metal alloy such as gold or nickel or nickel palidium gold. The pattern is determined by the interconnection path between the lower and upper surfaces 14, 18 of the substrate 12.

Next, as illustrated in FIG. 3G, a solder resist film 58 is formed on the upper surface of the foil 50, i.e., over the trace metal 56. Then, as illustrated in FIG. 3H, the patterned and laminated foil 50 is exposed, developed, and thermally cured, which forms a pattern 60 on the upper surface of the foil 50. FIG. 3I illustrates an electrolytic plating process being performed in which a conductive metal 62 such as gold is plated over the pattern 60 on the upper surface of the foil 50. Then, as shown in FIG. 3J, another solder resist film 64 is formed of laminated onto the plated pattern on the upper surface of the foil 50. FIG. 3K illustrates another step of exposure, development and thermal curing (similar to as shown in FIG. 3H), which forms yet a further pattern 66 in the upper surface of the foil 50. FIG. 3L illustrates the patterned upper surface of the foil 50 undergoing a seeding and electrolytic plating process, in which a conductive metal 68 such as gold is formed over the top surface of the foil 50. Alternatively, an electroless plating process could be performed to deposit the conductive metal 68 on the patterned surface of the foil 50.

In FIG. 3M, a step of forming or laminating yet another solder resist film 70 over the upper surface of the foil 50 is shown, and in FIG. 3N, another step of exposure, development and thermally curing is performed to further develop a pattern 72 on the surface of the foil 50, and FIG. 3O illustrates a further conductive metal 74, such as gold, being plated onto the surface of the pattern 72. The build-up layers formed on the surface of the foil 50 illustrated in FIGS. 3A-3O illustrate how the substrate 12 is formed. Thus, in FIG. 3O, the substrate 12 is shown as formed on the upper surface of the foil 50.

FIG. 3P illustrates the formation of the side walls 38 formed on the upper surface of the foil 50 over the plated pattern 72. The side walls 38 form housing areas 76, in which packaged devices will be assembled. As previously discussed, the side walls 38 may be formed using a conventional molding process. The mold tool used to form the side walls has several inserts. The inserts contact the substrate upper surface 18 forming a path to form the four sided wall during the molding process. Although only two housing areas 76 are shown, it will be appreciated by those of skill in the art that either a strip or an array of housing areas 76 may be simultaneously formed on the surface of the foil 50.

FIG. 3Q illustrates the removal of the foil 50 from the now formed substrate 12. The foil 50 may be removed by etching. In one alternative embodiment of the invention, the foil 50 is removed before the formation of the side walls 38, and in another embodiment of the invention, the foil 50 is not removed until after the dies 22, 26 and 32 have been attached to the substrate 12.

Referring now to FIG. 3R, the first die 22 and the pressure sensor die 26 are attached to the surface of the substrate 12 within the housing areas 76 using known die bonding techniques. For example, the dies 22 and 26 (and 32) may be attached to the surface of the substrate 12 using a die attach adhesive or a double sided tape (not shown). The die attach adhesive is subsequently cured in an oven to harden the die attach adhesive. FIG. 3S illustrates the dies 22 and 26 (and 32) being electrically connected to each other and to the substrate 12 with bond wires 24, 28 and 30, via a standard wire bonding process and using conventional wire bonding equipment. Although not shown, another way of electrically connecting the first die 22 to the substrate 12 would be a flip-chip with bumps and then have the sensor dies 26 and 32 connect to the first die 22 by way of a wiring pattern in the substrate 12, with the sensor dies 26 and/or 32 having bond wires from their contact pads to contact pads of the substrate 12.

FIG. 3T illustrates the gel 40 being deposited or dispensed over the dies 22, 26 (and 32) and the bond wires 24, 28, 30 (and 36), while FIG. 3U illustrates the lids 42 being secured over the housing areas 76 by attaching ends of the lids to the side walls 38. The gel 40 may be dispensed with a nozzle of a conventional dispensing machine, as is known in the art. Subsequently, the gel 40 is cured in an oven. The lids 38 may be secured within the notches 46 in the side walls 38 using a conventional lid attach adhesive. Finally, FIG. 3V illustrates adjacent devices 10 being separated by a singulation process, such as with a saw, laser cutting, or scribing and cutting, etc.

The present invention, as described above, allows for packaging a pressure sensor die without requiring lead frames or especially pre-molded lead frames to package the die. The pressure sensor die packaged using the process described above is protected from moisture by the gel material, the lid and the substrate. It is noted that, because there is no lead frame and especially no pre-molded lead frame, the sensor device of the present invention exhibits improved reliability even in view of a rapid decompression event (RDE). For a lead frame or pre-molded lead frame type device that undergoes an RDE, air bubbles may travel up the path between the mold compound and the metal lead frame. Yet another benefit of the present invention is that the due to the relatively soft nature of the solder mask included in the substrate, then a device in accordance with the present invention is better able to absorb stress without cracking or breaking.

By now it should be appreciated that there has been provided an improved packaged pressure sensor die and a method of forming the packaged pressure sensor die. Circuit details are not disclosed because knowledge thereof is not required for a complete understanding of the invention. Although the invention has been described using relative terms such as “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A method of packaging a pressure sensor die, comprising the steps of:
forming a coreless substrate on a sheet of metal foil, wherein the forming includes forming one or more die attach areas and a plurality of electrical contacts on an upper surface of the substrate;
forming side walls at predetermined locations on the upper substrate upper surface;
attaching a first die to a first one of the die attach areas;
attaching a pressure sensor die to a second one of the die attach areas;
electrically connecting the first die to the plurality of electrical contacts on the substrate upper surface;
electrically connecting the pressure sensor die to the first die;
dispensing a gel material onto a top surface of at least the pressure sensor die; and
attaching a lid over the first die and the pressure sensor die, wherein the lid is supported by the side walls.

2. The method of packaging a pressure sensor die of claim 1, further comprising removing the metal foil from the substrate to expose a bottom surface of the substrate.

3. The method of packaging a pressure sensor die of claim 2, wherein removing the metal foil is performed before the side walls are formed on the upper surface of the substrate.

4. The method of packaging a pressure sensor die of claim 2, wherein removing the metal foil is performed after the side walls are formed on the upper surface of the substrate.

5. The method of packaging a pressure sensor die of claim 1, wherein the electrical connection steps comprise performing a wire bonding process to connect the first die to the substrate with first bond wires and to connect the pressure sensor die to the first die with second bond wires.

6. The method of packaging a pressure sensor die of claim 1, wherein forming the side walls comprises performing a molding process and forming the side walls with a mold compound.

7. The method of packaging a pressure sensor die of claim 1, further comprising attaching a third die to a third die attach area and electrically connecting the third die to the first die.

8. The method of packaging a pressure sensor die of claim 7, wherein the third die comprises an accelerometer.

9. The method of packaging a pressure sensor die of claim 1, wherein the dispensing step includes covering the first die with the gel material.

10. The method of packaging a pressure sensor die of claim 1, wherein the lid is formed of metal and includes a through hole.

11. The method of packaging a pressure sensor die of claim 1, further comprising the step of curing the gel material.

12. A packaged pressure sensor die, comprising:
a coreless substrate having a lower surface with exposed electrical contacts and an upper surface with exposed substrate contact pads and one or more die attach areas;
a first semiconductor die attached to a first one of the die attach areas and electrically connected to the substrate contact pads;
a pressure sensor die attached to a second one of the die attach areas and electrically coupled to the first semiconductor die;
a sidewall formed on the upper surface of the substrate;
a gel covering at least the pressure sensor die; and
a lid covering the first semiconductor die and the pressure sensor die, wherein the lid is supported by the side walls.

13. The packaged pressure sensor die of claim 12, further comprising first bond wires that electrically connect the first semiconductor die to the substrate contact pads and second bond wires that electrically connect the pressure sensor die to the first semiconductor die.

14. The packaged pressure sensor die of claim 12, wherein the sidewalls are formed of a mold compound and include notches that receive ends of the lid.

15. The packaged pressure sensor die of claim 15, wherein the lid is formed of metal and includes a through-hole.

16. The packaged pressure sensor die of claim 12, further comprising an accelerometer die attached to a third die attach area on the surface of the substrate and electrically connected to the first semiconductor die with third bond wires.

17. The packaged pressure sensor die of claim 12, wherein the packaged pressure sensor die comprises a quad flat no-leads (QFN) package.

18. A packaged pressure sensor die, comprising:
a coreless substrate having a lower surface with exposed electrical contacts and an upper surface with exposed substrate contact pads and one or more die attach areas;
a control die attached to a first die attach area and electrically connected to the substrate contact pads;
a pressure sensor die attached to a second die attach area and electrically connected to the control die;
an accelerometer die attached to a third die attach area and electrically connected to the control die;
a sidewall formed on the upper surface of the substrate;
a gel covering at least the pressure sensor die; and
a lid covering at least the pressure sensor die, wherein the lid is supported by the side walls.

19. The packaged pressure sensor die of claim 18, further comprising first bond wires that electrically connect the control die to the substrate contact pads, second bond wires that electrically connect the pressure sensor die to the control die, and third bond wires that electrically connect the accelerometer die to the control die.

20. The packaged pressure sensor die of claim 18, wherein the sidewalls are formed of a mold compound and include notches that receive ends of the lid, the lid is formed of metal and includes a through hole, and the lid covers the control die, the pressure sensor die and the accelerometer.
